(19) United States
(12) Patent Application Publication
(10) Pub. No.: US 2009/0139562 A1
(43) Pub. Date: Jun. 4, 2009

(54) Portable photovoltaic window system

(76) Inventor: Donald Lee Thomas, Hampton, VA (US)

Correspondence Address: Donald Lee Thomas, 2508 Victoria Blvd., Hampton, VA, 23661, US

(21) Appl. No.: 12/292,974

(22) Filed: Dec. 2, 2008

Related U.S. Application Data
(60) Provisional application No. 61/005,021, filed on Dec. 3, 2007.

(51) Int. Cl. H01L 31/042

(52) U.S. Cl. 136/245

(57) ABSTRACT

A portable, lightweight and detachable photovoltaic window system affording a resource for converting solar power in existing buildings and similar structures. At least one photovoltaic panel is interconnected to a building window or entrance casing or directly to a window pane through use of lanyards, hook and loop fasteners, or suction cups. Solar energy is captured from direct sunlight incidental to the location of the window. A panel may be removably supported by a fabric material interconnected to an interior wall via hook and loop fasteners. An inverter converts energy from DC to AC for powering electrically driven devices. A pocket is provided on the panel support for temporarily storing the auxiliary devices. This system enables a person with little knowledge of solar energy equipment a convenient and inexpensive method to convert sunlight into useful energy without major alterations to the building or window unit being used as a light-source.

### CROSS-REFERENCE TO RELATED APPLICATIONS

All priority benefits under 35 USC 119(e) of Provisional Patent Application Ser. No. 61/005,021 filed Dec. 3, 2007 are hereby claimed and the contents thereof in their entirety incorporated herein by reference. The present invention is the subject matter of a Disclosure Document filed in the United States Patent and Trademark Office on Aug. 4, 2006 and registered as No. 604318. All benefits of said registered Disclosure Document are claimed under 35 U.S.C. Section 122, 37 C.F.R. Section 1.14, and MPEP section 1706. The present application also is related to applicant's application Ser. No. 10/241,855 filed Sep. 13, 2002, which was published Mar. 18, 2004 as 2004 0050507, subsequently issued as U.S. Pat. No. 6,848,492 on Feb. 1, 2005, and the contents thereof in their entirety are hereby incorporated herein by reference.

### FEDERALLY SPONSORED RESEARCH

Not Applicable

### SEQUENCE LISTING

Not Applicable.

### BACKGROUND OF THE INVENTION

1. Field of the Invention

This invention relates in general to the technological field of portable photovoltaic (PV) systems, and more particularly to the applications of such systems in buildings or houses to produce electricity for powering devices and appliance in the absence of (or as supplement to) more conventional power resources.

One of the principal drawbacks of known portable electric power producing systems such as electric generators and the like, is that their. operation generally relies on non-renewal energy sources such as batteries, gasoline, diesel fuel or similar petroleum based products. In the event of remote and/or portable operation of these devices where conventional electricity utility service is unavailable or for some reason not operational, the equipment user will need access to batteries or power systems driven by petroleum based products for equipment operation. An additional drawback is that burning of petroleum based products adds carbon emissions to the earth's atmosphere.

With the noted drawbacks mentioned above and considering the frequently escalated cost of fossil fuels, increasing attention is being paid to renewable energy sources such as solar and wind power. Solar power characteristically utilizes modules comprised of photovoltaic (PV) cells to produce electric current. These PV modules typically are installed in arrays of collection panels permanently mounted to building, for example on a rooftop. In most building applications, photovoltaic (PV) solar units are permanently roof-top mounted devices.

What is needed is a fully portable renewable energy system that can be conveniently placed and repositioned by hand as necessary to capture energy from the sun so as to power devices such as computers, small appliances, alarms, emergency lighting and communication systems such as radios and television sets. More particularly, a system is needed that would fit snuggly within a window or door frame so as to be directly impacted by outside solar energy, and readily movable to another window or doorway as necessary to follow solar position changes for operational efficiency.

2. Description of the Prior Art

Thomas' U.S. Pat. No. 6,848,492 discloses an inexpensive lightweight, reusable and detachable insulating cover device for residential and commercial dwellings and similar heated structures. The inner-portion of the insulating pad fit inside of a typical entrance or window unit framing. The outer-portion of the insulating pad overlaps the window unit or entrance framing.

The outer portion of Thomas' insulating pad may be secured to the building wall structure surrounding the window or entrance framing by using hook and loop type fasteners available under the Velcro® brand name. During cold weather months, the Thomas insulating cover device will restricts warm air from escaping between small crevices in inept window systems by fitting firmly into window framing using an insulating material, thus creating a thermal barrier and improving the efficiency of the furnace and lessening electricity or fuel consumption.

Fronek's U.S. Pat. No. 6,646,196 discloses a multi-panel window structure with a photovoltaic panel permanently affixed in the window unit. While Fronek provides an alternative to roof-mounted PV panel arrays, it is still a permanently mounted feature and not easily removed, changed and/or upgraded. A major drawback of current solar applications is that they are expensive and permanently mounted roof-top structures, and with no emphasis placed on portability.

Using the earth's wind currents to produce energy is another well known renewal energy source. While this form of renewal energy has promise, it requires open spaces of land and tall wind vane columns, clearly not feasible for portable and emergency energy production purposes. Compactness, stability and ease of assembly in remote and emergency locations are highly desirable aspects of any portable renewal energy devices.

Azzam, in U.S. Pat. No. 6,974,904 presents a portable solar powered unit which features a wheeled frame. This technology does offer a compact and portable means to provide electrical power in remote locales and emergency situations. It is suited for use in remote, isolated and underdeveloped regions of the world such as deserts and small villages that lack energy infrastructure. However, this particular solar powered unit is an item of relativity high cost and typical consumers would not be willing to make so high a capital investment for an item of such limited use. Azzam's units are believed to be better suited for commercial applications rather than used by the everyday consumer/homeowner.

Typically when building integrated photovoltaic (BIPV) units are incorporated into fixed roof mounted structures, the weight of these units must be considered in roof load designs by architects and home designers. Also, current BIPV units are not suited for portable, compact, lightweight micro-solar energy applications. Accordingly, there is a need for a portable, flexible, compact and lightweight BIPV unit that is configured to face a window unit when installed permitting it to be exposed to direct sunlight, thus producing solar electric energy. In event of a power outage this portable BIPV device can serve as a back-up source of electric energy.

Also included in the prior art is a portable solar technology for automotive use. Sundar's U.S. Pat. No. 4,955,203 features an air conditioning unit for a parked automotive vehicle. Electricity to power the vehicle air conditioning system is produced by a portable solar panel located interiorly near the front window of the vehicle.

While Sundar's disclosure presents a portable solar design, it does not allow for the portable solar panel to be conveniently withdrawn and repositioned in other automobile windows by detaching and relocating the solar panel. Thus, the scope and use of Sundar's system is severely limited in this respect. In addition, there is no suggestion that the Sundar device could be applied to various window openings in a building to supply electricity to any of a number of devices. While interchangeability of the solar panel is, in hindsight, conceivable in his design, Sundar makes no reference of this ability in his patent document and the venue or context of use described in no way suggests interchangeability. To the contrary, interchangeability and multiple applications are a major objective of the present invention which now will be described in more detail.

### BRIEF SUMMARY OF THE INVENTION

There has been a longstanding need for a portable building-integrated photovoltaic system that is both simple and cost effective to install at first application, and particularly one that does not damage or alter existing window, window framing or adjacent wall structures. The present invention provides a technique for generating solar power in existing buildings by using portable and removable fabric window coverings, an elastic cord lanyard array, hook fastener and/or suction cup attachment method/system to arrange solar panels in a position to best capture and convert solar energy from direct sunlight incidental to the location of the window itself.

Since the effectiveness of a solar collection panel is generally dependent upon its relative position to the sun, it is found that easy portability enables the user to selectively place the panel adjacent windows with more advantageous solar incidence. The present invention employs a lightweight and flexible fabric material which incorporates hook and loop fasteners (e.g., of the type available under the trade name Velcro®) and an elastic cord fastened around the perimeter of the fabric material. The hook and loop fasteners and elastic chord feature are used to secure the fabric material over the interior-side generally (or the exterior) of window units. A generally central portion of the fabric material incorporates sets of hook and loop fasteners employed in mounting at least one light weight solar panel.

While fabric material is described as a suitable support mount for the solar panel, this feature can be omitted completely and the solar panel could be secured in place directly at the window unit with a lanyard support array or suction cup attachment feature. Either of these applications will make the present invention a more universal device which could be used in more diverse building environments.

An important object of the present invention is to offer a person with little knowledge of solar energy equipment a quick and simple method to convert sunlight into solar energy without making significant alterations to the building or window unit being used as a light-source.

Another important object of the present invention is that in event of power outages, this device could serve as a back-up source to deliver electric power where needed. In communities ruined by natural or man-made disasters, this device allows victims an easy and low-cost means to operate household electrical devices until regular power service is restored.

Still another object of the present invention is that this reusable device could be among the equipment supplied in an emergency response kit. The early response teams could install these unique devices in disaster command centers and use them to produce electrical power for their mobile communication equipment and medical apparatus. This device will also work well as a supplemental electrical power source for recreational vehicles (RVs) and used as a back-up recharging source in electrical automobiles.

The present invention could be modified to incorporate thermal insulating material inside the layers of fabric window covering thus making the device a reusable dual energy conservation and alternative energy producing device.

The present invention will be better understood and appreciated from the following detailed description of one embodiment thereof, selected for purposes of illustration and shown in the accompanying drawings.

### BRIEF DESCRIPTION OF THE VARIOUS VIEWS OF THE DRAWINGS

FIG. 1 is a perspective view of an exterior house structure with the present invention installed;

FIG. 2 is an elevation view of the front window facing side of the present invention with the solar panel unit installed;

FIG. 2A is a exploded side elevation view showing a schematic of various parts used to assemble the present invention as illustrated in FIG. 2 and FIG. 5.

FIG. 2B is a modified side elevation exploded similar to the FIG. 2A showing a schematic the various parts used to assemble the present invention, while omitting optional features;

FIG. 3 is an elevation view of the front window facing side of the present invention similar to FIG. 2 but without the solar panel unit installed;

FIG. 4 is a partial elevation of an exterior house structure showing the installation of the present invention;

FIG. 5 is an elevation view of the rear, room facing, side of the present invention;

FIG. 6 is a partial elevation of an interior house structure showing the installation of the present invention;

FIG. 6A is a partial elevation of an interior house structure showing the installation of the wall-affixed hook and loop fastener elements;

FIG. 6B is a partial elevation of an interior house structure showing the installation of the wall-affixed fastening mounts.

FIG. 6C are detailed orthographic views of the wall fastening mounts shown in FIG. 6B;

FIG. 7 is a partial elevation of an interior house structure showing the installation of the present invention, omitting the fabric window covering and using the lanyard support array;

FIG. 7A is a front and side elevation view of the solar panel with the optional solar panel mounts as illustrated in FIG. 7.

FIG. 7B is a front elevation view of the solar panel with the optional full perimeter solar panel mount;

FIG. 7C is a side and front elevation of the mounting lanyard used in FIG. 7;

FIG. 7D is a modified elevation view of FIG. 7 wherein sill and window frame mounts are employed to install the inventive device;

FIG. 7E is a modified elevation view resembling view FIG. 7, this view shows a suction cup installation design of the patent invention;

FIG. 7F show the three optional fastening devices discussed in other drawings, displaying different mounting features;

FIG. 7G is a front and side elevation view of the solar panel with the optional solar panel mounts as illustrated in FIG. 7 and the optional suction cup attachment feature.

### DETAILED DESCRIPTION OF THE INVENTION

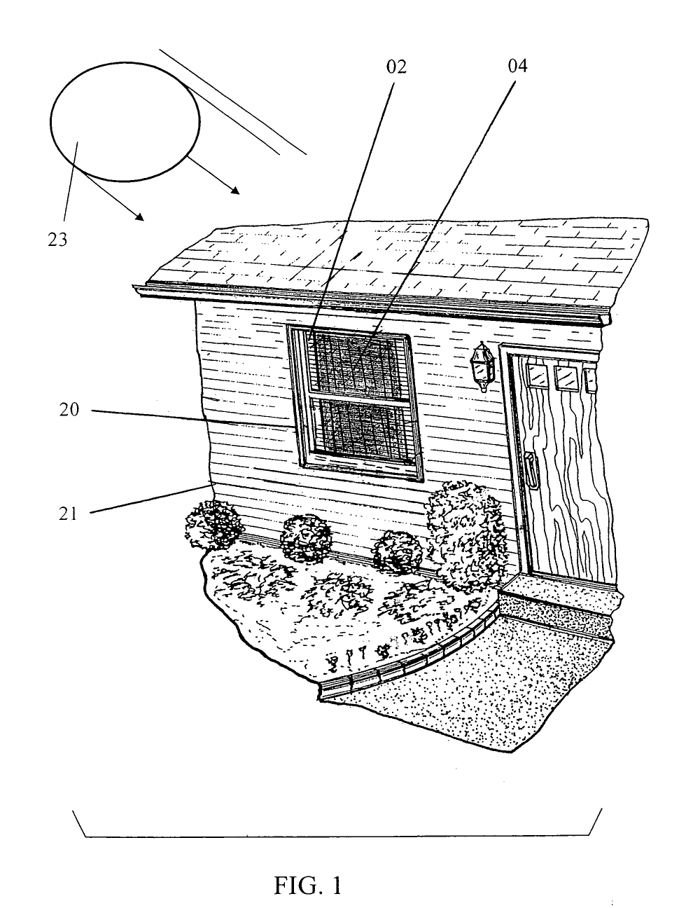

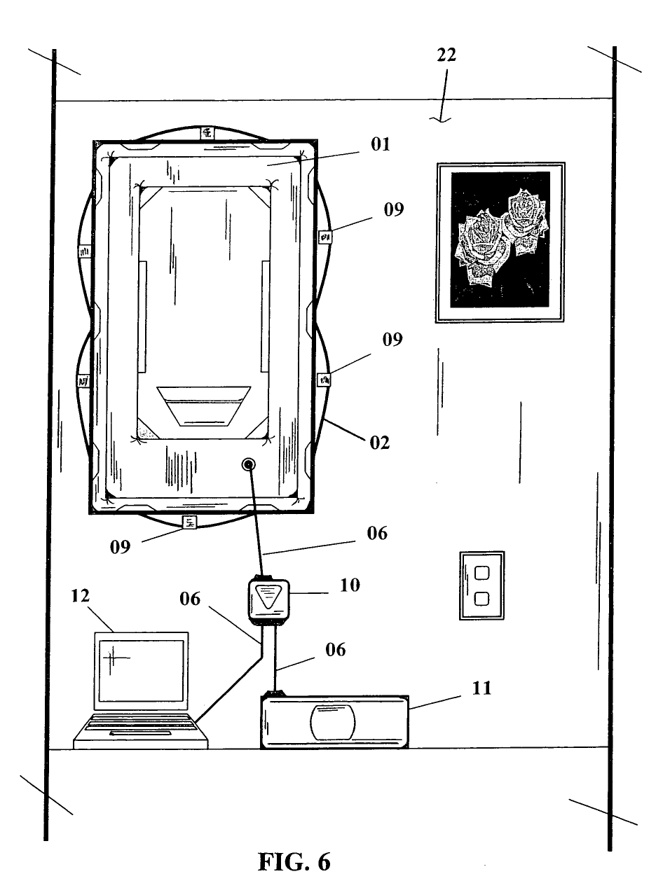

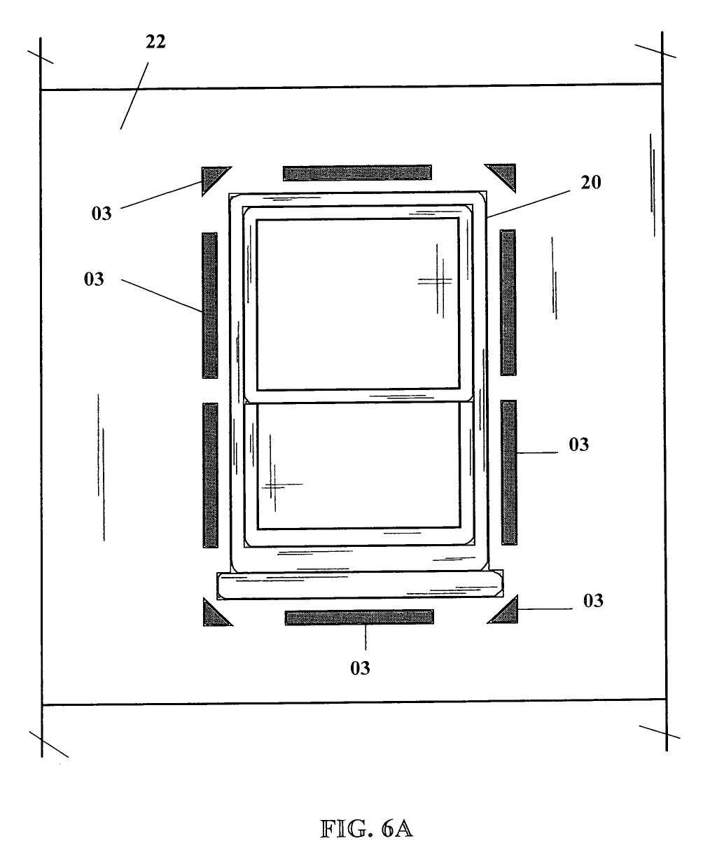

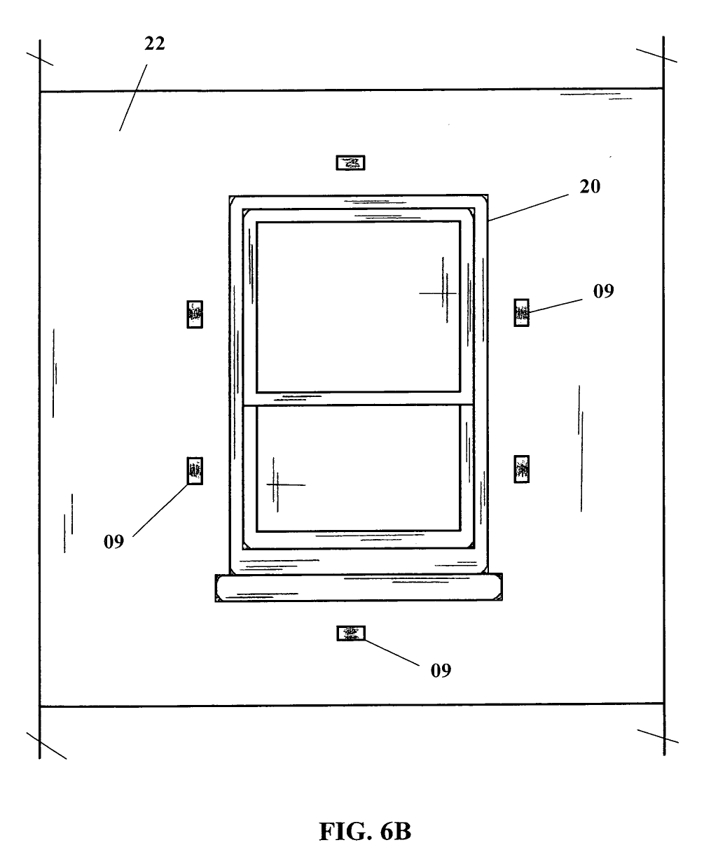

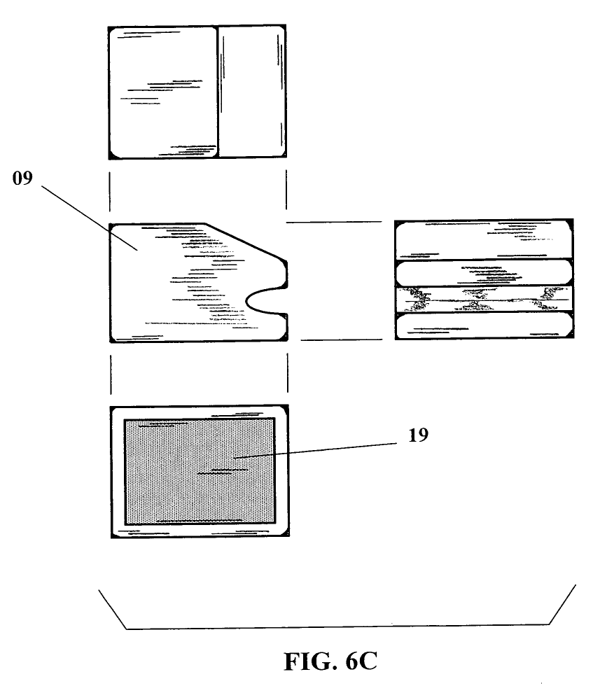

Illustrated in FIG. 1 is a perspective view of an exterior house or building structure 21 with the present invention installed. In this (FIG. 1) illustration the present invention is installed on the interior side of window unit 20 depicted as positioned within an opening defined in a house or building wall 22. This installation is fully illustrated in FIG. 6. The solar panel 04 is attached to the fabric window covering 01 and positioned in a manner to convert solar energy from direct sunlight incidental to the location of the window unit 20 itself.

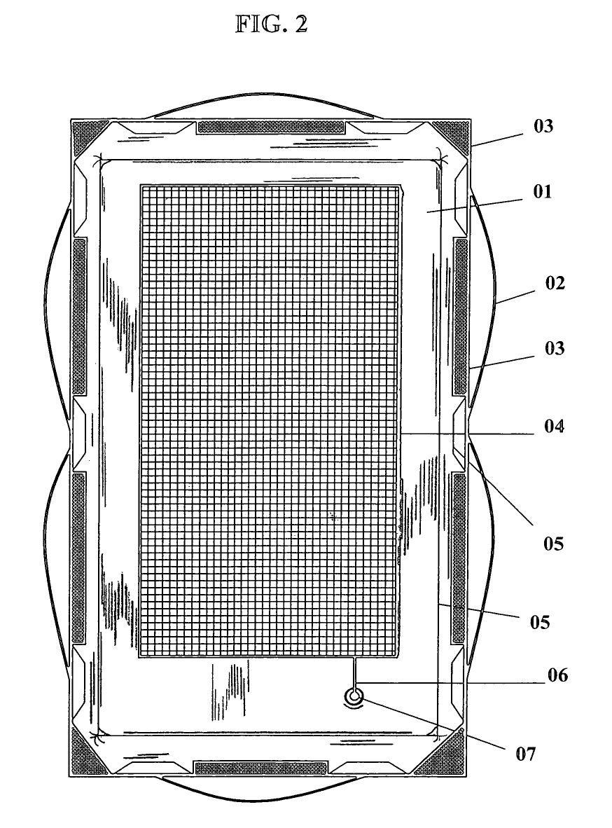

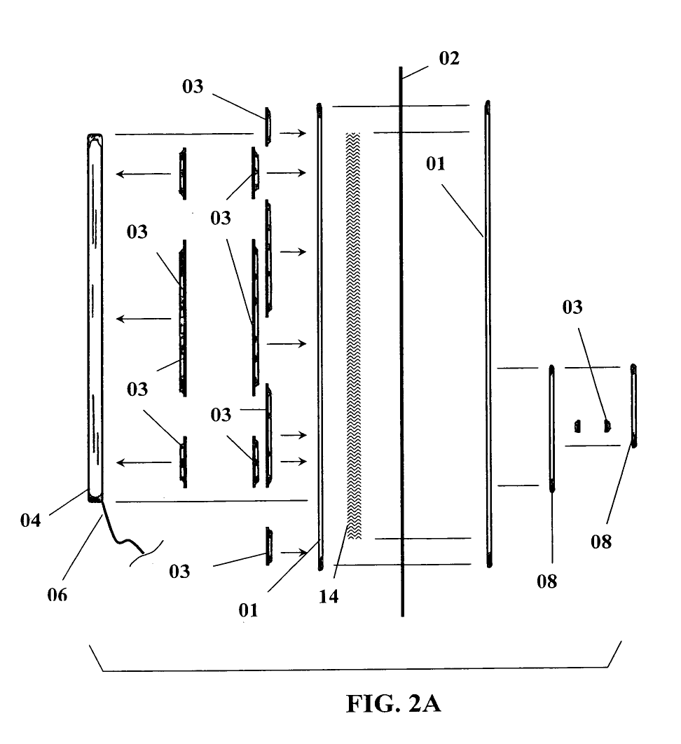

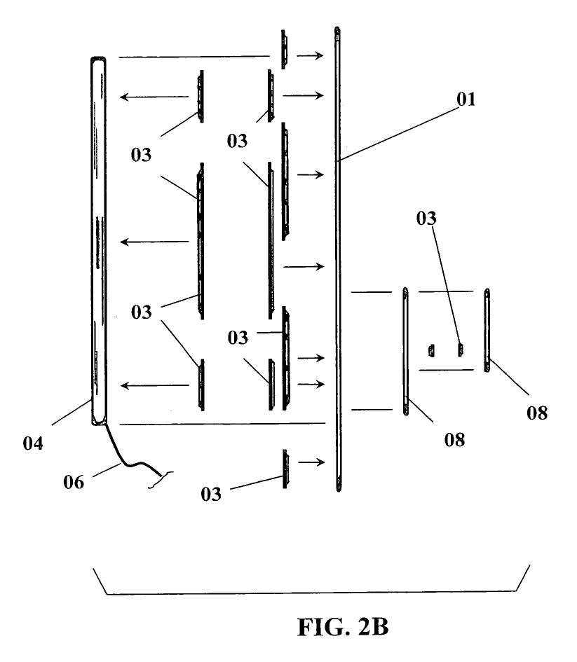

An elevation view depicted in FIG. 2 shows the front or outward window-facing side of the present invention with the solar panel unit 04 installed. Shown in this view is a fabric window covering 01 used as a mounting support for an installed solar panel unit 04. The solar panel unit 04 is centered on said fabric window covering 01 in a manner that when installed the solar panel unit is located facing (outwardly toward) direct sunlight incidental to the building window or defined opening. The covering 01 may be configured to fully cover a window (or doorway) recess typical of such framed openings. This offers the added features of insulating the opening and positioning the solar panel unit 04 outwardly (into the recess) to its maximum extent to take advantage of solar incidence.

The solar panel unit 04 may be secured to, and supported by, the fabric window covering 01 using uniformly spaced hook and loop fasteners 03 (or their equivalents); these fasteners are affixed along the perimeter of the non-photovoltaic cell side (or rearward facing side) of solar panel unit 04 in direct alignment with corresponding hook/loop fastener elements 03 affixed to fabric window covering 01. Along the perimeter of the front window-facing side of the fabric window covering 01 are also uniformly spaced hook and loop fasteners 03 (or their equivalents).

These fastener elements are deployed to attach the photovoltaic device and its support to the area bordering around the window unit. Besides hook and loop fasteners, these elements may also include any other conventional fastening means, for example snaps or hooks, threaded or non-threaded fasteners and so forth. The present invention includes an optional mounting method using elastic cord material 02.

The fabric window covering 01 can, if desired, be fabricated to comprise two (or more) layers of material. The layers of covering 01 may be sewn together or joined using threading material 05 such as nylon or other high strength threading. Of course, a stapling technique or other equivalent fastening process may be employed such as adhesives, heat seal, and the like. Once attached, the elastic cord material 02 may be looped around the perimeter of the fabric window covering 01 as illustrated in FIG. 2. The elastic cord material 02 is uniformly spaced and firmly attached to covering 01. Where fabric layers are utilized, the cord material 02 may be tucked in segments and firmly anchored between the joined layers of fabric window covering 01. Attached to the solar panel 04 is electrical wiring in the form of a power cord 06. The cord 06 penetrates the fabric window covering 01 using cover penetration opening 07.

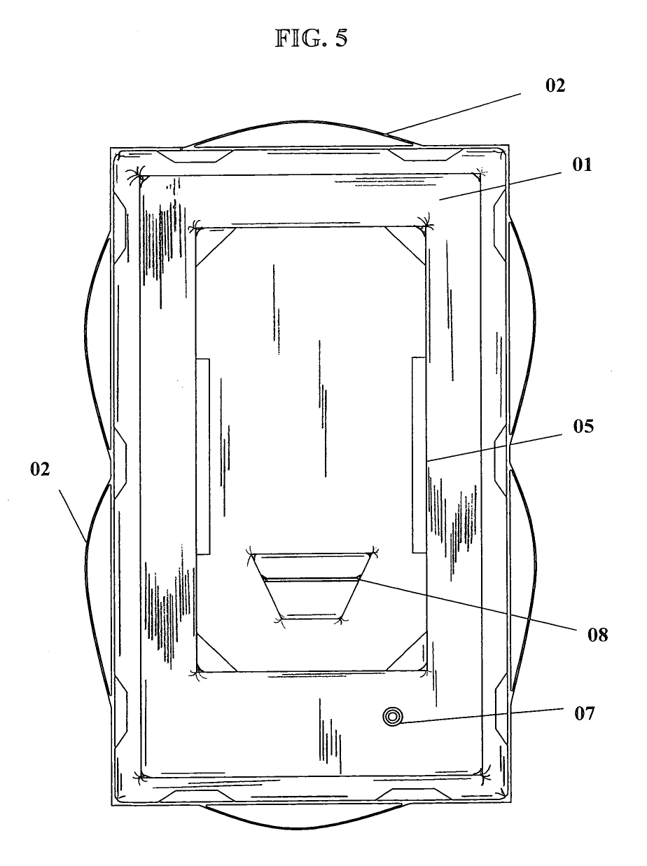

An exploded view presented as FIG. 2A is a simple illustration of the various components of the present invention. FIGS. 2 and 5 show the alignment and placement of the components as fully assembled. FIG. 2A illustrates an optional insulation material 14 (between layers of fabric covering 01) and further shows uniformly spaced hook and loop fasteners 03. Again, any suitable equivalent fastener means may be employed. A modified exploded view of FIG. 2A is illustrated by FIG. 2B which eliminates optional features such as insulation material 14, elastic cord material 02 and one layer of the fabric window covering 01. While a storage pouch 08 is shown, it also is optional and could be omitted, if desired.

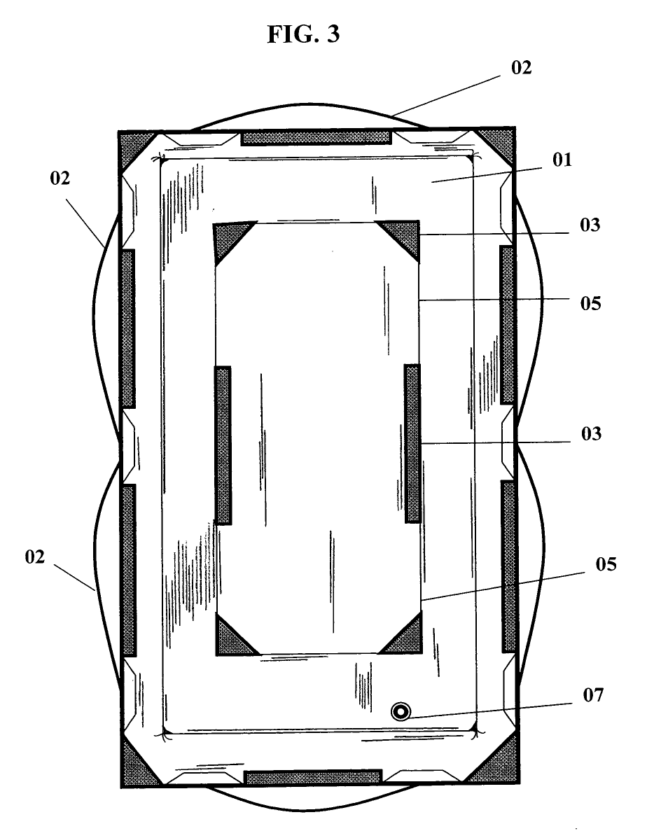

The front window-facing (or outwardly facing) surface of the present invention is illustrated in elevation FIG. 3, but without the solar panel unit installed. This view incorporates all the features and attributes of FIG.2 except the solar panel unit 04 and (electrical wiring) power cord 06 have been omitted to show the corresponding hook and loop fasteners 03 affixed to fabric window covering 01.

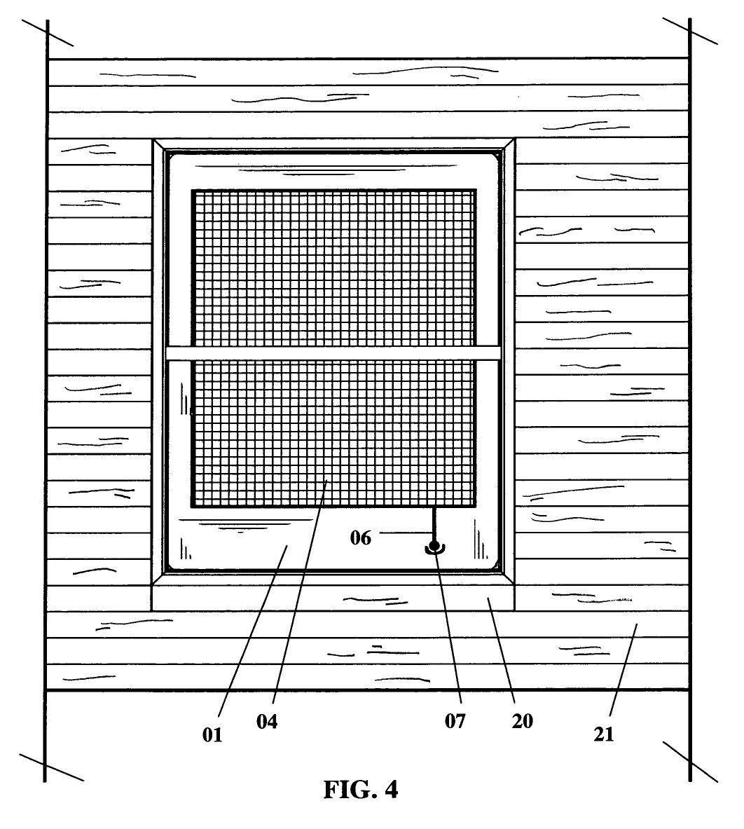

A partial elevation view, FIG. 4, depicts exterior house structure 21 revealing the installation of the present invention. The present invention is installed on the room-side (i.e., interior) of the window unit 20 (or other wall opening) thus positioning the solar panel unit 04 in a manner that the component will be exposed to direct sunlight incidental to the location of the window unit 20. The room-side (inside) installation of the present invention is illustrated with greater detail in FIG. 6.

FIG. 5 is an elevation view of the room-facing (rearward or inwardly facing) side of the present invention. This view incorporates all the features and attributes of FIG. 2 except the solar panel unit 04, power cord 06 and hook and loop fasteners 03 which are omitted. Sewn to the fabric window covering 01 is a storage pouch 08. This storage pouch 08 provides a convenient method to store the electrical power inverter 10 and power cord 06 or other items as may be desired. The fabric window covering 01 and the optional storage pouch 08 are sewn and assembled together using nylon threading material 05 in a manner as illustrated in the exploded view FIG. 2A.

FIG. 6 is a partial elevation of an interior house structure 22 further describing the installation of the present invention. This partial elevation view shows an interior house structure 22 with the portable photovoltaic window unit installed over a window unit 20 (not visible in this view). An outer perimeter of the photovoltaic panel supporting fabric window covering 01 overlaps onto a wall area surrounding the window unit 20 (again, not visible in this view).

The electrical wiring or power cord 06 is shown passing through the cover penetration opening 07 (see FIG. 5), then to the electrical power inverter 10 and onward toward a point of application. The inverter 10 serves to convert solar direct electrical current (DC) to alternating electrical current (AC). In this illustration one power cord 06 branches off to support an AC electrical device 12 and the other branches off to a DC storage battery 11 or similar charging system; while not shown, this same power cord 06 can by-pass the inverter 10 and connect directly to the DC storage battery 11. Also note the optional elastic cord 02 element employed as a mounting support to secure the present invention in place by attachment to wall fastening mounts 09.

FIG. 6A is a partial elevation of an interior house structure showing the installation of wall-affixed hook and loop fasteners 03. These uniformly spaced hook and loop fasteners 03 are installed around the window unit 20 in a manner that they will be in direct alignment with corresponding hook and loop fasteners 03 installed on the present invention as illustrated in FIG. 2. As is well known in the art, either hook units or loop units may be placed on the wall and/or the device as long as they engage attachable opposites.

Shown in FIG. 6B is a partial elevation of an interior house structure showing the installation of the wall-affixed fastening mounts. These wall fastening anchors in the form of mounts 09 will be used as an optional device mounting system to secure the present invention over the window unit 20 (or other defined wall opening) using elastic cord material 02. This elastic cord material 02 is installed on the present invention as illustrated in FIG. 2. These fastening mounts 09 are uniformly spaced around the window unit 20 and are used to secure the present invention in place as illustrated in FIG. 6.

FIG. 6C presents detailed orthogonal views of the present invention's wall fastening mount 09. This drawing shows the top, front, right-side and bottom orthographic sides of wall fastening anchor or mount 09. Note the bottom (wall facing) side of this mount 09 component has an adhesive 19 applied to it. This adhesive 19 will be used to secure the fastening mount 09 directly to the surrounding wall surface. The form of the fastening mounts 09 is not to be considered limiting, as any equivalent, conventional fastening method or system will suffice, for example (but not limited to) hooks, straps, cords, lacing, braces, clamps and the like.

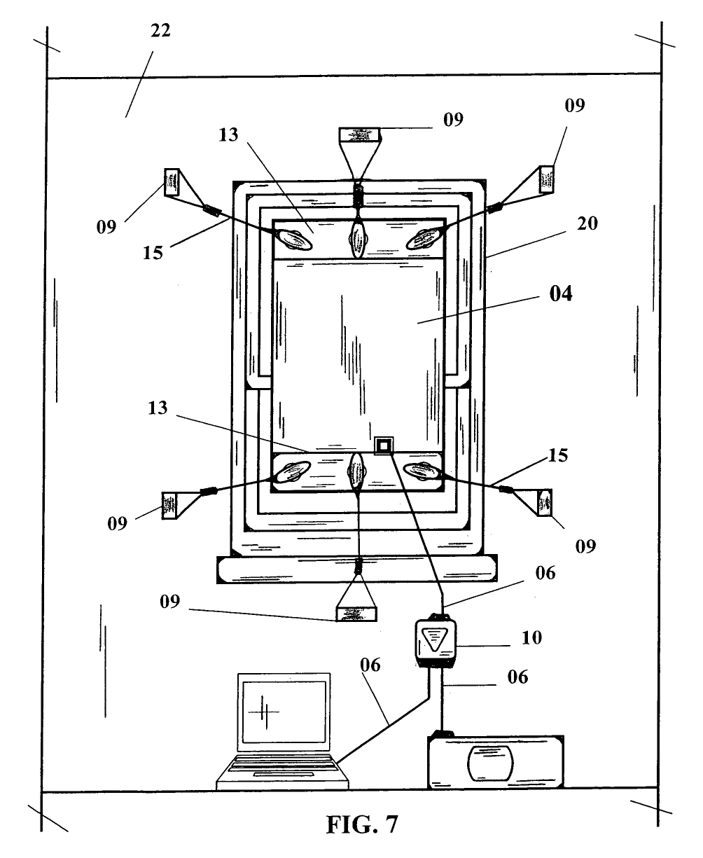

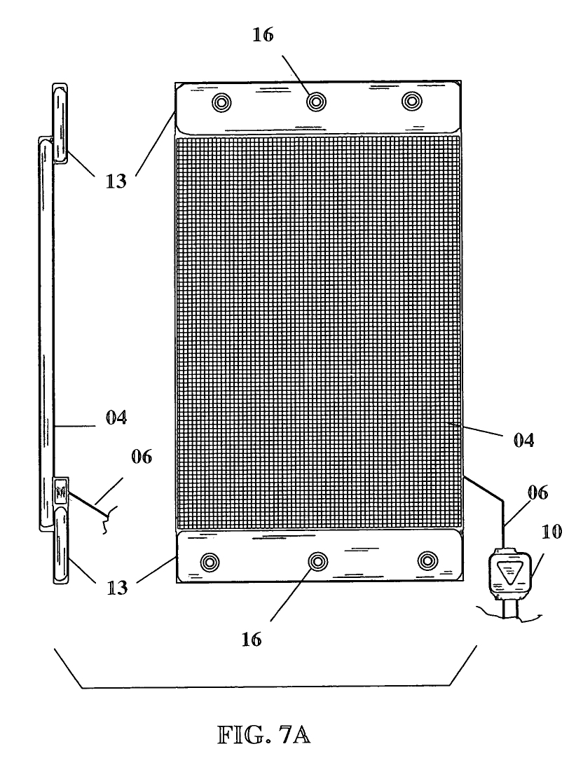

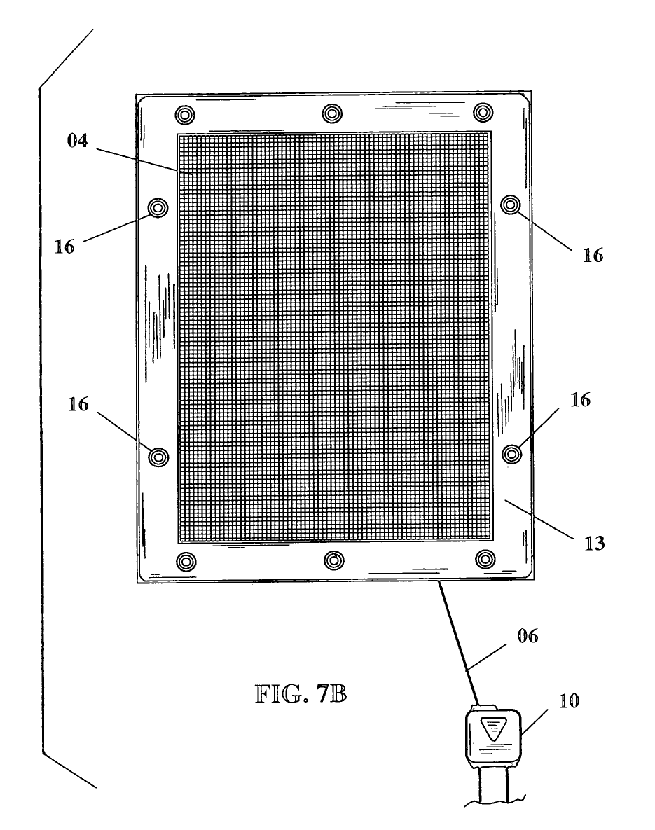

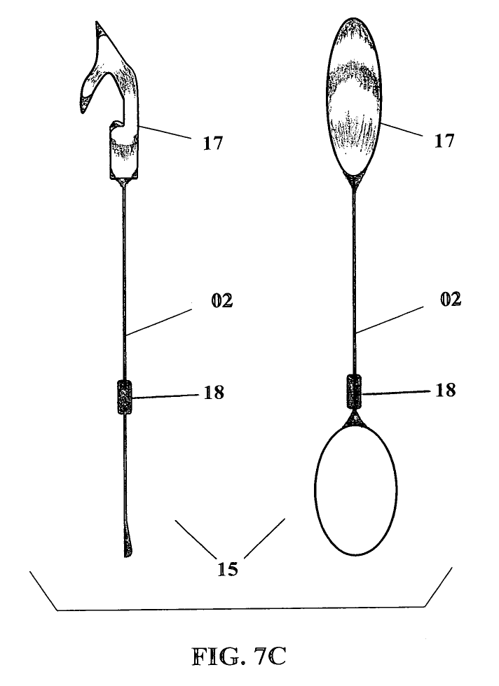

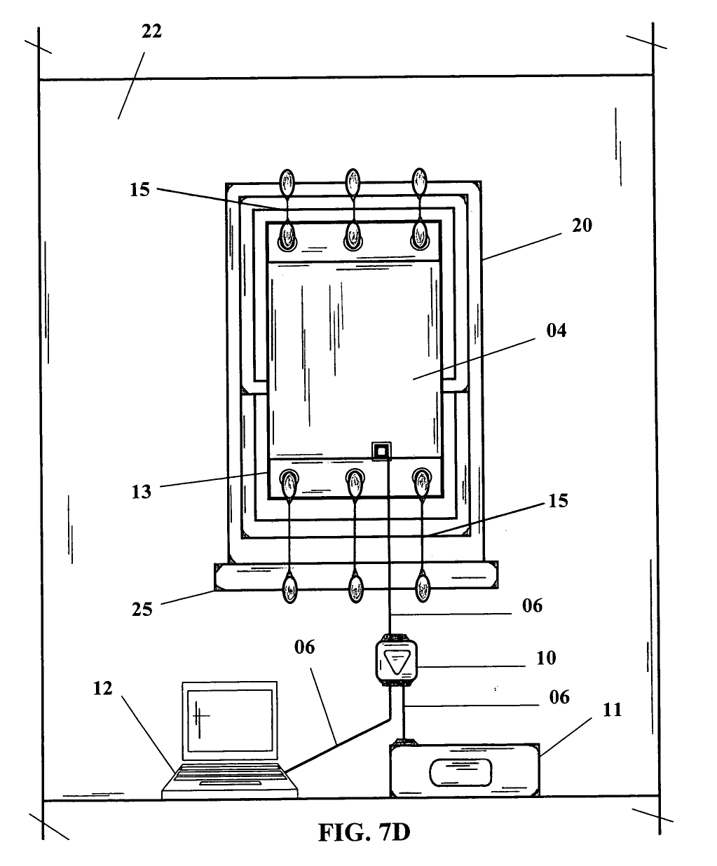

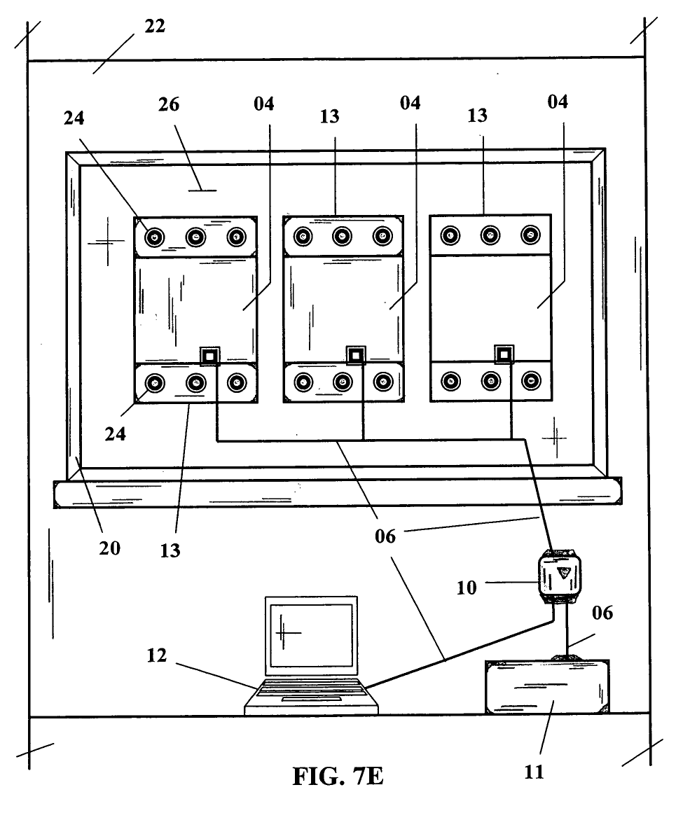

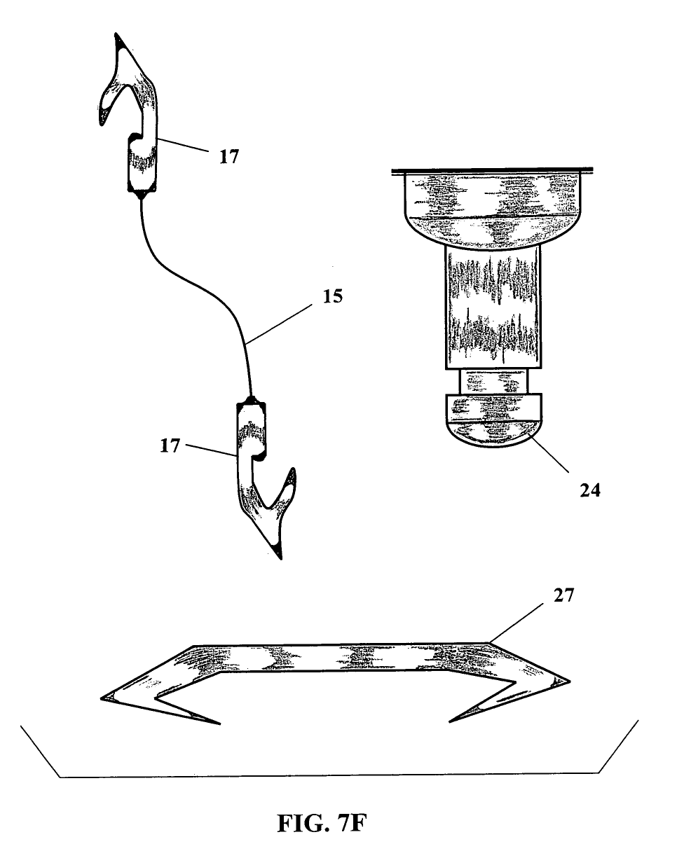

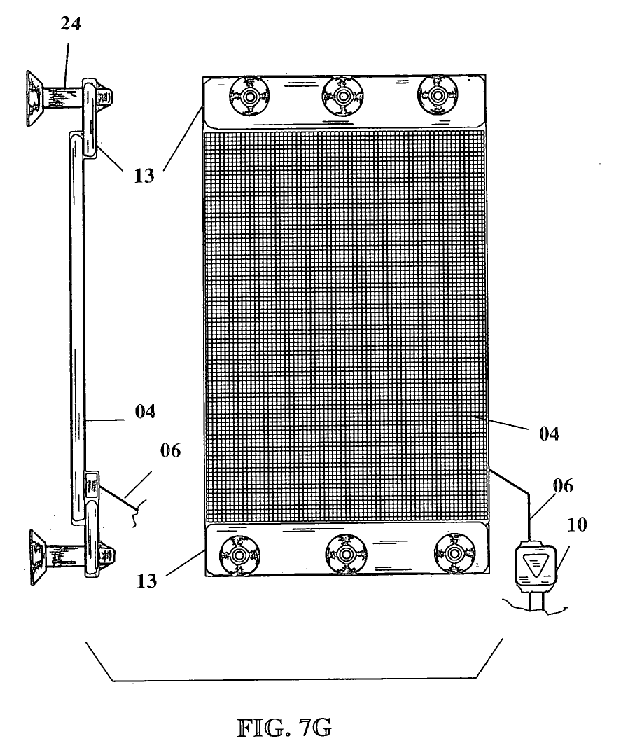

A partial elevation is presented by FIG. 7 showing an interior house structure 22 including the installation of the present invention. This partial elevation view shows an interior house structure 22 with the portable photovoltaic panel installed over a window unit 20. The fabric material covering 01 has been entirely omitted and functionally supplanted by a lanyard support array for the solar panel 04. With the lanyard support array the solar panel is set and maintained in position using a series of uniformly spaced mounting lanyards 15. These mounting lanyards 15 are braced around wall fastening mounts 09 and firmly connected to the solar panel mounts 13.

Solar panel mounts 13 are securely attached to the solar panel 04 using an adhesive, by sewing, or affixed by mechanical means. The power cord 06 is then routed to the electrical power inverter 10 which (as explained hereabove) changes the solar direct current (DC) to alternating current (AC). In this illustration one power cord 06 branches off to support an AC electrical device 12 and the other branches off to a DC storage battery 11 or similar charging system; while not shown, this same power cord 06 can by-pass the inverter 10 and connect directly to the DC storage battery 11.

FIG. 7A is a front and side elevation view of the solar panel with optional solar panel support mounts 13. Support mounts 13 are affixed to solar panel 04 in any of a variety of ways including, but not limited to, adhesives, sewing, or mechanical elements. Note the eyelet 16 features allowing the mounting lanyard 15 to be firmly attached to solar panel mount 13 as illustrated in FIG. 7. The term eyelet 16, by the way, is intended to connote any of a variety of well known mechanical fixtures which can serve as discrete anchors to which loops, cords and the like can be applied for securement.

FIG. 7B is a front elevation view of the solar panel 04 showing it optionally supported about its full perimeter by a modified panel mount 13. This view shows the solar panel mount 13 attached on all sides of solar panel 04. This feature will of course provide multidirectional support for solar panel 04.

A side and front elevation of the mounting lanyard 15 used in FIG. 7 is illustrated in FIG. 7C as having first and second ends. Mounting lanyard 15 has three primarily components including loop or hook 17, elastic cord material 02 and clamp 18. The clamp 18 will firmly secure a looped segment of the elastic cord material in a manner that will allow section mounting lanyard 15 to have a fastening end. The loop or hook 17 is firmly attached to the opposite end of the elastic cord material 02. In use, the loop or hook 17 will firmly attach about eyelet 16 of the solar panel mount 13 as illustrated in FIG. 7. “Eyelet” in the present context refers to a fixed anchor element which may or may not include an opening.

FIG. 7D is a modified elevation view of FIG. 7. This partial elevation view shows an interior house structure 22 with the portable photovoltaic window panel 04 installed over window unit 20. Note in this modification that the wall fastening mounts 09 have been completely removed, thus saving time and steps in the installation process. This variation of the lanyard support array uses the optional dual-hook mounting lanyard 15 to install the present invention in the following manner.

Along the top protruding edges of window unit frame 20 a first end of mounting lanyard 15 is secured firmly by its hook 17 and the lanyard 15 second end has its hoop 17 secured on a corresponding eyelet 16 of the solar panel mount 13. At least one lanyard 15 is thus attached at opposite edges of solar panel mount 13 so as to secure it in place relative to window unit 20. As illustrated, for example, three lanyards 15 are employed by hooks 17 at the top frame 20 edge and bottom sill 25. The opposing ends of the lanyards 15 are looped to corresponding eyelets 16 on the solar panel mounts 13. The eyelet 16 feature is clearly depicted in FIG. 7A.

These solar panel mounts 13 are securely attached to the solar panel 04 using an adhesive, sewn or other mechanical elements. As described hereabove, the power cord 06 is then routed to the electrical power inverter 10 which in turn alters the collected solar direct electrical current (DC) to alternating electrical current (AC). In this illustration one power cord 06 branches off to support an AC electrical device 12 and the other branches off to a DC storage battery 11 or similar charging system; while not shown, this same power cord 06 can by-pass the inverter 10 and connect directly to the DC storage battery 11.

FIG. 7E is a modified view as compared to that depicted in FIG. 7. The FIG. 7E view shows a window unit 20 reconfigured to depict one large fixed single glass pane window. Illustrated here, for example is an array of three solar panel units 04 mounted directly to the window glass pane 26 using optional suction cup fasteners 24. More than, or fewer than, three solar panels may clearly be applied. As described above, solar panel mounts 13 are securely attached to firmly support the solar panels 04 using an adhesive, by sewing or employing other mechanical means.

Each suction cup fastener 24 is inserted through an eyelet 16 (or other suitable openings extending through solar panel mounts 13), forming a releasable interconnection between the solar panel mounts 13 and the window glass pane 26. Using manually applied compressive force, the faces of suction cup fasteners 24 collectively attach to the window glass pane 26, thus installing the solar panels 04. The power cords 06 for all three solar panels 04 are then routed to the electrical power inverter 10. Again, this inverter serves to convert collected solar direct electrical current (DC) to alternating electrical current (AC). In this illustration, as before, one power cord 06 branches off power inverter 10 to support an AC electrical device 12 and the other branches off to a DC storage battery 11 or similar charging system; while not shown, this same power cord 06 can by-pass the inverter 10 and connect directly to the DC storage battery 11. The application of the suction cup fastener 24 is covered in greater detail in FIG. 7G.

FIG. 7F is a detailed view of three optional fastening devices discussed in other drawings. The first fastening device described is the modified mounting lanyard 15 with two opposed mounting hooks 17 as illustrated in FIG. 7D. These opposed hooks 17 are firmly connected to the centered elastic cord material 15. The second device is the suction cup fastener 24. The use of this latter device is illustrated in FIG. 7E and FIG. 7G. The third device is a modified mounting lanyard 15 which omits the elastic cord 17 feature of the other designs. This rigid connector 27 design can replace other mounting lanyards 15 where the additional elastic cord is not needed.

FIG. 7G is a modified front and side elevation view of the solar panel with the optional solar suction cup fastener 24 installed onto the solar panel mounts. The suction cup fastener 24 is affixed firmly in the eyelet 16 feature of the solar panel mount 13; this eyelet 16 feature is fully illustrated in FIG. 7A. The application of the suction cup attachment feature is fully illustrated in FIG. 7E.

It is important to note that the fabric window covering 01 may be made of any suitable material such as flame retardant material, cotton, plastic, polyester, paper or plastic with aluminum foil backing, nylon, and the like. In addition this fabric window covering 01 can be made from a durable transparent or translucent polymer or other conventional material having these properties.

The optional insulation material 14 may be any conventional type of insulation such as polyester batting, fiberglass, bubble-foil insulation, plastic, cotton, rubber and any conventional insulation material including flame retardant material which is designed to resist the transfer of heat through its surface. The eyelets 16 on the solar panel mounts 13 are not to be considered as limiting since any form of clamps, brackets, bolting or equivalent conventional fastening means can be used.

In addition to hook and loop fasteners 03, other fasteners could be used such as snaps, hooks or any other types of conventional fastening means. While nylon threading material 05 has been mentioned, it will obvious that in addition to nylon threading material 05, snap fasteners, staples, hot seals, epoxy or other glue-like material can be used. In addition the elastic cord material 02 may substituted with other suitable products.

An additional advantage of the present invention is that its portable and lightweight design. While the present invention is presented as a home or house appliance, it could well find application outside the home. For example, it would make an excellent auxiliary electrical power device for recreation vehicles (RVs) and spacecraft. This device could supplement the solar power generation abroad aircraft and spacecraft, or on boats, as well as serve as a emergency backup power source in virtually any location.

Although the foregoing description makes reference to a number of specific features and embodiments, these should not be construed as limiting the scope of the present invention. Instead, the described invention should be viewed as susceptible of modification, combinations and alterations. Accordingly, the following claims are intended to cover all such modifications which are within the spirit and scope of the invention. In other words, the scope of the invention should be determined by the appended claims and their equivalents, rather than limited in any manner by the examples given.

I claim:

1. A portable photovoltaic device including at least one photovoltaic panel interconnected to an associated electric wiring system and inverter, wherein said panel device is configured for placement within at least one window in a building wall structure, and wherein said window is recessed within a defined wall opening having a surrounding framing area and outer framing edges, and said window including at least one glass pane positioned within said framing area, said photovoltaic panel device further including:
a photovoltaic panel mounting support including fasteners for securely engaging said photovoltaic panel to said mounting support for releasably holding said photovoltaic panel in position adjacent said at least one glass pane so as to gain advantageous solar incidence therewith;
said fasteners configured for manual engagement and disengagement so as to install, remove and replace said portable photovoltaic panel within said framing area without surface damage or alteration to said panel, wall or defined wall opening;
said mounting support member further configured to enable uninterrupted passage of said associated wiring to said inverter;
whereby solar energy may be collected by said photovoltaic panel device and fed as electricity to a point of application where it is used by at least one electrically operated device and said portable panel device may be readily removed for storage or for non-damaging placement in another defined wall opening with advantageous solar incidence.

2. The portable photovoltaic panel device of claim 1, further distinguished by:
said photovoltaic panel mounting support comprising a fabric material to which said panel is removably affixed;
said fabric material is configured to extend across said defined wall opening and removably attached to said wall structure adjacent said surrounding framing area.

3. The device of claim 2 further defined by said fabric being attached to said wall structure by releasable hook and loop fastener elements.

4. The device of claim 2 further defined by said fabric being attached to said wall structure by an elastic cord element.

5. The device of claim 2 further defined by:
said wall structure having removable anchor fixtures adjacent said surrounding framing;
said fabric being releasably attached to said wall structure by at least one lanyard element.

6. The device of claim 2 further defined by:
said fabric includes plural coextensive layers mutually joined;
an additional insulation layer disposed between at least two of said layers.

7. The portable photovoltaic device of claim 1 further distinguished by:
said photovoltaic panel mounting support fasteners include at least one suction cup fastener configured to be removably secured directly to said at least one glass pane.

8. The portable photovoltaic device of claim 1 further distinguished by:
said device including more than one photovoltaic panel each of which includes a panel mounting support and fasteners for securely engaging said panel to said mounting member for releasably holding said photovoltaic panel in position adjacent said at least one glass pane.

9. The portable photovoltaic device of claim 1 further defined by:
at least some of said fasteners each comprising a lanyard element with a hook member affixed to at least one end thereof and configured to directly engage at least one of said outer framing edges.

10. The portable photovoltaic device of claim 1 further defined by:
said panel mounting support is provided with at least one eyelet anchor element;
at least some of said fasteners comprising a lanyard element with a loop member affixed to at least one end thereof and configured to directly engage at least one of said eyelet anchor elements on said panel mounting support.

11. The portable photovoltaic device of claim 1 further distinguished by:
said photovoltaic panel mounting support includes a first side facing outwardly in a first direction toward said glass pane and said photovoltaic panel, and a second side facing inwardly in a direction opposite said first direction and toward said point of application;
said second side of said photovoltaic panel mounting support further including a storage pouch configured to temporarily store said inverter and electric wiring system when not in use.

12. A portable photovoltaic device including at least one photovoltaic panel interconnected to an associated electric wiring system and inverter, wherein said panel device is configured for placement within at least one opening in a building wall structure, and wherein said opening is recessed within a defined wall opening having a generally surrounding framing area and outer framing edges, and said at least one opening having exposure to solar incidence, said photovoltaic panel device further including:
a photovoltaic panel mounting support including fasteners for securely engaging said photovoltaic panel to said mounting support for releasably holding said photovoltaic panel in position within said at least one opening so as to gain advantageous solar incidence therewith;
said fasteners configured for manual engagement and disengagement so as to install, remove and replace said portable photovoltaic panel within said framing area without surface damage or alteration to said panel, wall or defined wall opening;
said mounting support member further configured to enable uninterrupted passage of said associated wiring to said inverter;
whereby solar energy may be collected by said panel device and fed as electricity to a point of application where it is used by at least one electrically operated device and said portable panel device may be readily removed for storage or for non-damaging placement in another defined wall opening with advantageous solar incidence.

13. The portable photovoltaic panel device of claim 12, further distinguished by:
said photovoltaic panel mounting support comprising a fabric material to which said panel is removably affixed;
said fabric material is configured to extend across said defined wall opening and removably attached to said wall structure adjacent said surrounding framing area.

14. The device of claim 13 further defined by said fabric being attached to said wall structure by releasable hook and loop fastener elements.

15. The device of claim 12 further defined by:
said wall structure having removable anchor fixtures adjacent said surrounding framing;
said fabric being releasably attached to said wall structure by at least one lanyard element.

16. The device of claim 13 further defined by:
said fabric includes plural coextensive layers mutually joined;
an additional insulation layer disposed between at least two of said layers.

17. The portable photovoltaic device of claim 13 further defined by:
at least some of said fasteners each comprising a lanyard element with a hook member affixed to at least one end thereof and configured to directly engage at least one of said outer framing edges.

18. The portable photovoltaic device of claim 13 further defined by:
said panel mounting support is provided with at least one eyelet anchor element;
at least some of said fasteners comprising a lanyard element with a loop member affixed to at least one end thereof and configured to directly engage at least one of said eyelet anchor elements on said panel mounting support.

19. The portable photovoltaic device of claim 13 further distinguished by:
said photovoltaic panel mounting support includes a first side facing outwardly in a first direction toward said photovoltaic panel, and a second side facing inwardly in a direction opposite said first direction and toward said point of application;
said second side of said photovoltaic panel mounting support further including a storage pouch configured to temporarily store said inverter and electric wiring system when not in use.
